(19) United States
(12) Patent Application Publication
(10) Pub. No.: US 2024/0145302 A1
(43) Pub. Date: May 2, 2024

(54) SEMICONDUCTOR DEVICE AND METHOD FOR MANUFACTURING INTERCONNECTING METAL LAYER THEREOF

(71) Applicant: Taiwan Semiconductor Manufacturing Company, Ltd., Hsinchu (TW)

(72) Inventors: Yu-Shien SHIAH, Hsinchu (TW); Bor Chiuan HSIEH, Hsinchu (TW); Tsai-Jung HO, Hsinchu (TW); Meng-Ku CHEN, Hsinchu (TW); Tze-Liang LEE, Hsinchu (TW)

(73) Assignee: Taiwan Semiconductor Manufacturing Company, Ltd., Hsinchu (TW)

(21) Appl. No.: 18/099,771

(22) Filed: Jan. 20, 2023

Related U.S. Application Data
(60) Provisional application No. 63/421,671, filed on Nov. 2, 2022.

(51) Int. Cl. H01L 21/768; H01L 23/532; H01L 29/66

(52) U.S. Cl. CPC H01L 21/76843; H01L 21/76826; H01L 21/76831; H01L 21/76876; H01L 23/53266; H01L 29/66545

(57) ABSTRACT

A semiconductor device and a method for manufacturing an interconnecting metal layer thereof are provided. The semiconductor device includes a gate layer, a dielectric layer, an insulating layer, an epitaxial layer, and a sidewall liner. The dielectric layer is disposed on one side of the gate layer, the insulating layer is disposed on another side of the gate layer, the epitaxial layer is located on the insulating layer, and the sidewall liner penetrates the dielectric layer and the gate layer, and one end of the sidewall liner is connected to the epitaxial layer. The sidewall liner is converted from a high-k material to a low-k material by hydrogen and oxygen plasma treatments.

### PRIORITY CLAIM AND CROSS-REFERENCE

This application claims the benefit of U.S. provisional application Ser. No. 63/421,671, filed Nov. 2, 2022, the subject matter of which is incorporated herein by reference.

### BACKGROUND

In middle-end of line of semiconductor manufacturing process related to transistors, in order to control the critical dimension of the metal layer connected to the drain and prevent metal diffusion, it is essential to deposit a protective liner on the sidewall of the metal layer connected to the drain. Compared to low dielectric constant (low-k) materials such as silicon dioxide (SiO₂), silicon nitride (SiNx) has relatively high chemical stability against post-process damage. Therefore, silicon nitride (SiNx) is conventionally used as a protective liner. However, silicon nitride (SiNx) is a high dielectric constant material, which degrades the performance of overall circuit and the lifetime of thin film transistors will deteriorate accordingly. For the above reasons, it is needed to be further improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1C are schematic diagrams illustrating a method for manufacturing an interconnecting metal layer for preventing metal diffusion according to an embodiment of the present disclosure.

FIGS. 2A to 2E are schematic diagrams of a method for manufacturing a semiconductor device according to an embodiment of the present disclosure.

FIG. 3 is a schematic diagram of a semiconductor device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

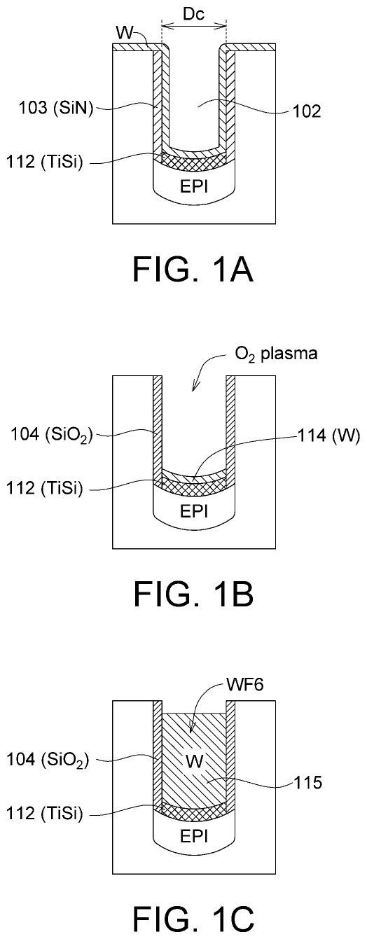

Please refer to FIGS. 1A to 1C. FIGS. 1A to 1C are schematic diagrams illustrating a method for manufacturing an interconnecting metal layer for preventing metal diffusion according to an embodiment of the present disclosure. The interconnecting metal layer in this embodiment is, for example, a metal layer connected to the source or drain. In FIG. 1A, in order to control the critical dimension (Dc) of the metal layer connected to the source or drain and prevent metal diffusion, a sidewall liner 103 is formed in a trench 102 first. The sidewall liner 103 are, for example, silicon nitride (SiNx) or other high-k materials. Next, a metal silicide 112 and a seed layer 114 are formed on the bottom of the trench 102, as shown in FIG. 1B. For example, the sidewall liner 103 is formed in the elongated trench 102 by chemical vapor deposition or physical vapor deposition, and then a part of the deposited material is removed by dry etching or wet etching to leave the sidewall liner 103 (SiNx) on the sidewalls of the trench 102. Then, the deposition material around the trench 102 is removed by chemical mechanical polishing. The metal silicide 112 is, for example, titanium silicide (TiSi). The titanium silicide (TiSi) can be turned into a low-resistivity metal silicide 112 through heat treatment. In addition, the seed layer 114 can be formed on the metal silicide 112, and the seed layer 114 is, for example, a metal such as cobalt (Co) or tungsten (W). For the electroplating process in which the metal layer is cobalt, electroplating is performed on the cobalt seed layer to form a large amount of cobalt on the seed layer 114. Due to the relatively high chemical stability of silicon nitride (SiNx), damage caused by the electroplating cobalt process is prevented. However, for the chemical vapor deposition process in which the metal layer is tungsten (W), WF₆ is mainly used as the tungsten raw material, and WF₆ reacts with SiH₄ to deposit tungsten as the seed layer 114. Next, at 400 degrees Celsius, WF₆ and H₂ react and a large amount of tungsten is deposited on the seed layer 114, as shown in FIG. 1C. Since tungsten hexafluoride (WF₆) is corrosive, the chemical vapor deposition process of tungsten will cause damage to silicon nitride (SiNx), it is not suitable to use silicon nitride (SiNx) as the sidewall liner 103.

Accordingly, in order to prevent silicon nitride (SiNx) from being damaged by post-process and reduce the protective barrier capability, a pre-process of SiNx is done, and silicon nitride (SiNx) is a high dielectric constant material, it has an adverse effect on the performance of thin film transistors. In this embodiment, prior to the chemical or physical vapor deposition of a large amount of tungsten on the seed layer 114, the silicon nitride (SiNx) is subjected to hydrogen-oxygen plasma treatments to convert the sidewall liner 103 from a high dielectric constant (high-k) material to a low dielectric constant (low-k) material, that is, silicon nitride (SiNx) is converted into silicon dioxide (SiO₂) and other materials. The dielectric constant of silicon dioxide (SiO₂) is about 4.3, and the dielectric constant of silicon nitride (SiNx) is about 6.83. Since the dielectric constant of silicon dioxide (SiO₂) is relatively small, the performance of the semiconductor device is improved. The symbol 104 (SiO₂) means that the silicon nitride (SiNx) has been converted into silicon dioxide (SiO₂) during SiN self oxidation process.

In addition, the conversion of silicon nitride (SiNx) into silicon dioxide can make the original thickness of the sidewall liner 103 (e.g., about 2 nm) maintain, and it is no need to additionally form a silicon dioxide film on the Silicon nitride (SiNx) to reduce the inner diameter of the trench 102 and the size of the metal layer 115, so the present embodiment can precisely control the critical dimension of the metal layer 115 connected to the source or drain, so as to improve the performance of the semiconductor device.

In addition, since the chemical vapor deposition process for the metal layer of tungsten has low damage to silicon dioxide (SiO₂), and silicon dioxide (SiO₂) exhibits a good barrier effect on the diffusion of tungsten to silicon, it is suitable to use silicon dioxide (SiO₂) as the sidewall liner 104 of tungsten plug.

In some embodiments, the hydrogen-oxygen plasma treatments includes thermal plasma oxidation. The thermal plasma oxidation is provided to introduce oxygen ion plasma in a high temperature environment to make silicon nitride (SiNx) react with oxygen ions to generate silicon dioxide (SiO₂). The reaction formula is one of the following four reaction formulas:

Si₃N₄+6O*→3SiO₂+2N₂

Si₃N₄+8O*→3SiO₂+2N₂O

Si₃N₄+14O*→3SiO₂+4NO₂

Si₃N₄+10O*→3SiO₂+4NO

The thermal plasma oxidation further includes introducing argon gas, hydrogen ion plasma and oxygen ion plasma in a high temperature environment to make more silicon nitride (SiNx) react with oxygen ions to generate silicon dioxide (SiO₂), the following process parameters of the hydrogen-oxygen plasma treatments are listed, but the following parameters are only an example, the present disclosure is not limited thereto.

| | | O₂ | H₂ plasma | O₂ plasma |
|---|---|---|---|---|
| | | plasma | (HO) | (HO) |
| Plasma | Process pressure | 100-1000 m | 10-200 | 10-200 |
| conditions | (T) | | | |
| | RF power (W) | 2000-4000 | 100-500 | 100-500 |
| | H₂ flow (sccm) | 3000-5000 | 4000-6000 | 0 |
| | Ar flow (sccm) | 0 | 0 | 100-1000 |
| | O₂ flow (sccm) | 3000-5000 | 0 | 1000-3000 |
| | Temp (° C.) | 100-500 | 100-500 | 100-500 |
| | Time (S) | 10-300 | 10-300 | 10-300 |

After the above-mentioned oxygen plasma treatment, part of the silicon nitride (SiNx) reacts with oxygen ions to form silicon dioxide (SiO₂). Next, a metal silicide 112 and a sub-layer 114 are formed on the bottom of the trench 102 and cleaned with deionized water for two times. The seed layer 114 includes, for example, fluorine-free tungsten (FFW), and the seed layer 114 has a predetermined thickness, e.g., less than 30 angstroms. Next, after the metal silicide 112 and the seed layer 114 are formed, more silicon nitride (SiNx) reacts with oxygen ions to generate silicon dioxide (SiO₂) by hydrogen and oxygen plasma treatments until most of the silicon nitride (SiNx) is converted into silicon dioxide (SiO₂).

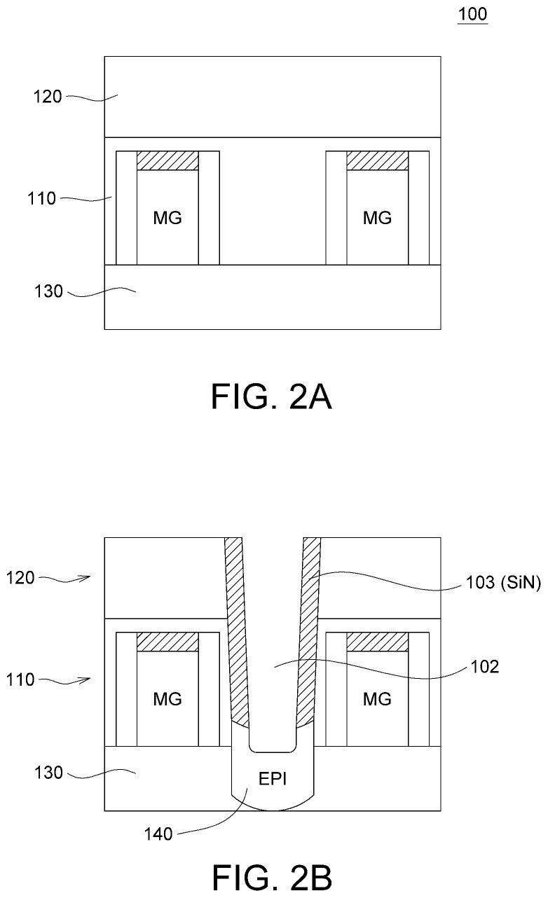

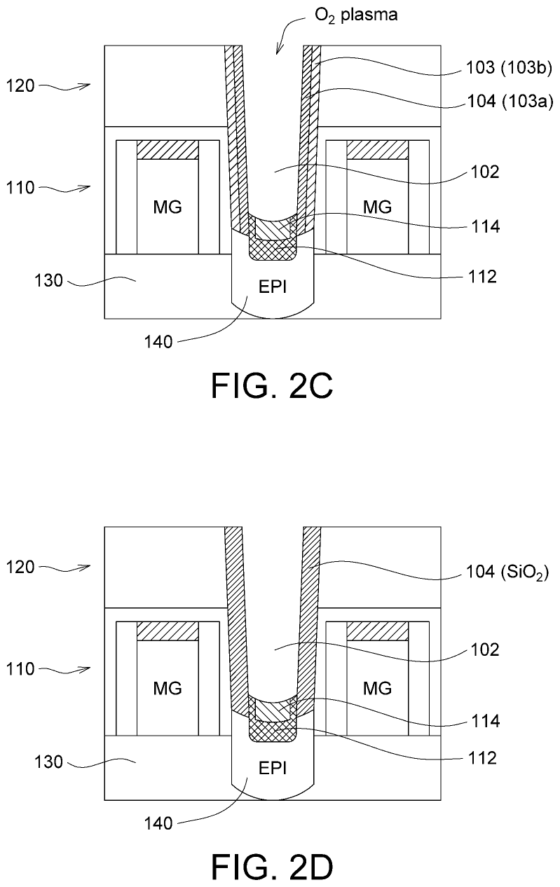

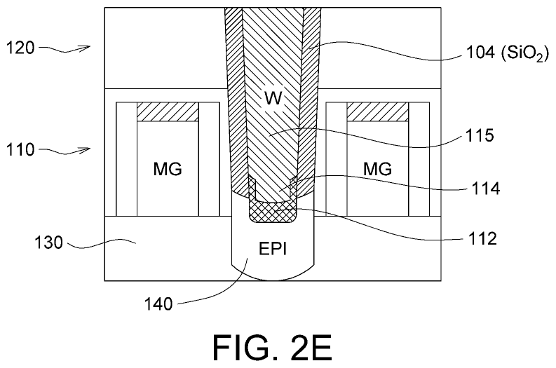

Please refer to FIGS. 2A to 2E. FIGS. 2A to 2E are schematic diagrams of a method of manufacturing a semiconductor device 100 according to an embodiment of the present disclosure. As shown in FIG. 2A, the semiconductor device 100 includes a gate layer 110, a dielectric layer 120, and an insulating layer 130. The dielectric layer 120 is disposed on one side of the gate layer 110, and the insulating layer 130 is disposed on the other side of the gate layer 110, the following manufacturing method of the semiconductor device 100 includes the following steps. As shown in FIG. 2B, a trench 102 is formed, the trench 102 passes through the dielectric layer 120 and the gate layer 110, and the epitaxial layer (EPI) 140 is formed at the bottom of the trench 102. Next, a sidewall liner 103 is formed on the sidewall of the trench 102, and one end of the sidewall liner 103 is connected to the epitaxial layer 140. The epitaxial layer 140 is, for example, a silicon-germanium compound, and the silicon-germanium (SiGe-based) epitaxial layer 140 is deposited by, for example, metal-organic vapor phase epitaxy (MOVPE) or silicon-germanium-on-insulator (SiGe-on-Insulator) method. In some embodiments, a silicon germanium (SiGe-based) compound is added in the source and drain of the transistor to reduce the resistance of the source and the drain and the leakage current of the transistor due to the lower energy gap characteristics of silicon germanium. In addition, the metal silicide 112 and the seed layer 114 can also be formed at the bottom of the trench 102. The metal silicide 112 is, for example, titanium silicide (TiSi), and the seed layer 114 is, for example, a metal such as tungsten, fluorine-free tungsten (FFW), etc. The metal silicide 112 is located between the seed layer 114 and the epitaxial layer 140 to serve as a barrier layer connected between the metal layer and the epitaxial layer 140, and the seed layer 114 can be used as a nucleation layer for growing bulk metal layer (e.g., tungsten).

Next, as shown in FIGS. 2C and 2D, the hydrogen and oxygen plasma treatments are performed on the sidewall liner 103 to convert the sidewall liner 103 from a high dielectric constant material to a low dielectric constant material. In FIG. 2C, the sidewall liner 103 includes a surface layer 103a and a bottom layer 103b, the bottom layer 103b is a silicon nitride (SiNx) layer, the surface layer 103a is a silicon dioxide (SiO₂) layer, wherein the surface layer 103a is formed by a part of silicon nitride (SiNx) reacting with oxygen ions to generate silicon dioxide (SiO₂). In FIG. 2D, the silicon nitride (SiNx) of the bottom layer 103b continues to react with oxygen ions to form silicon dioxide (SiO₂) until most of the silicon nitride (SiNx) is converted into silicon dioxide (SiO₂).

Next, as shown in FIG. 2E, a metal layer 115 (e.g., tungsten) is formed in the trench 102 by chemical or physical vapor deposition. The metal layer 115 is connected to the epitaxial layer 140, and the sidewall liner 103 are separated between the metal layer 115 and the gate layer 110. The present disclosure can be applied to metal layers with small apertures and high aspect ratios to meet the packaging requirements of high-density semiconductor devices 100 (e.g., transistors).

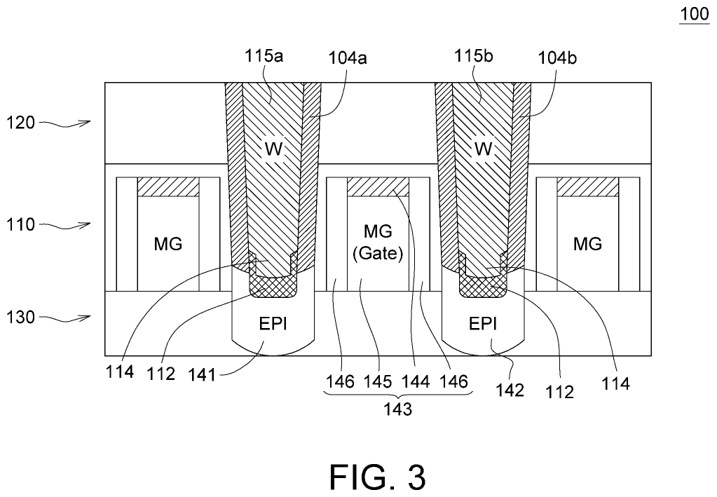

Please refer to FIG. 3. FIG. 3 is a schematic diagram of a semiconductor device 100 according to an embodiment of the present disclosure. The semiconductor device 100 includes a gate layer 110, a dielectric layer 120, an insulating layer 130, a first epitaxial layer 141 and a second epitaxial layer 142. The dielectric layer 120 is disposed on one side of the gate layer 110, the insulating layer 130 is disposed on the other side of the gate layer 110, and the first epitaxial layer 141 and the second epitaxial layer 142 are formed on the insulating layer 130. The manufacturing method of the interconnecting metal layer of the semiconductor device 100 is similar to that in FIGS. 2A to 2E, and the drawings are not shown here, but are only described in words. First, a first trench 102 and a second trench 102 are formed, the first trench 102 and the second trench 102 pass through the dielectric layer 120 and the gate layer 110. The first epitaxial layer 141 is formed at the bottom of the first trench 102, and the second epitaxial layer 142 is located at the bottom of the second trench 102. Next, a first sidewall liner 103 is formed on the sidewall of the first trench 102, and one end of the first sidewall liner 103 is connected to the first epitaxial layer 141. A second sidewall liner 103 is formed on the sidewall of the second trench 102, and one end of the second sidewall liner 103 is connected to the second epitaxial layer 142. Afterwards, hydrogen and oxygen plasma treatments are performed on the first sidewall liner 103 and the second sidewall liner 103, so that the first sidewall liner 103 and the second sidewall liner 103 are converted from a high dielectric constant (high-k) material to a low dielectric constant (low-k) material. Next, a first metal layer 115a is formed in the first trench 102, the first metal layer 115a is connected to the first epitaxial layer 141, and the first sidewall liner 104a is separated from the first metal layer 115a and the gate layer 110. In addition, a second metal layer 115b is formed in the second trench 102, the second metal layer 115b is connected to the second epitaxial layer 142, and the second sidewall liner 104b is separated from the second metal layer 115b and the gate layer 110 between.

The first epitaxial layer 141 and the second epitaxial layer 142 can be used as the source electrode and the drain electrode of the transistor, and the gate electrode layer 110 includes a gate electrode 143 located between the first metal layer 115a and the second metal layer 115b. A channel region is formed between the source electrode and the drain electrode, and the gate electrode 143 is located above the channel region for applying a gate voltage to control the current flowing through the channel. In some embodiments, the material of the gate electrode 143 includes chromium (Cr), molybdenum (Mo), copper (Cu), aluminum (Al), tungsten (W), titanium (Ti) or a combination thereof, but the disclosure is not limited thereto. The insulating layer 130 is formed under the gate electrode 143. The insulating layer 130 may be a dielectric material including silicon oxide (SiOx), aluminum oxide (AlOx), hafnium oxide:zirconium oxide (HfOx:ZrOx), hafnium oxide:aluminum oxide (HfOx:AlOx), hafnium oxide:lanthanum oxide (HfOx:LaOx), hafnium oxide:silicon oxide (HfOx:SiOx), hafnium oxide:strontium oxide (HfOx:SrO), hafnium zirconium oxide (HZO) doped with cerium oxide (CeOx), etc. In some embodiments, the gate electrode 143 may include a gate dielectric layer 144, a gate conductive layer 145 (such as metal gate, MG) and spacers 146. The gate dielectric layer 144 is formed on top of the gate conductive layer 145. The spacers 146 may include oxide layer and nitride layer (not shown) and are formed to cover sidewalls of the gate dielectric layer 144 and the gate conductive layer 145.

The present disclosure relates to a semiconductor device and a method for manufacturing an interconnecting metal layer thereof for improving the reliability of semiconductor device, wherein a sidewall liner is formed on the trench sidewall of the metal layer connected to the epitaxial layer, and the sidewall liner is separated from the metal layer and the gate layer. During the SiN self oxidation process, the sidewall liner is converted from a high-k material to a low-k material by hydrogen-oxygen plasma treatments, so as to achieve the effect of controlling the critical dimension of the metal layer and preventing metal diffusion.

According to an embodiment of the present disclosure, a semiconductor device is provided, which includes a gate layer, a dielectric layer, an insulating layer, an epitaxial layer, and a sidewall liner. The dielectric layer is disposed on one side of the gate layer, the insulating layer is disposed on another side of the gate layer, the epitaxial layer is located on the insulating layer, and the sidewall liner penetrates the dielectric layer and the gate layer, and one end of the sidewall liner is connected to the epitaxial layer. The sidewall liner is converted from a high-k material to a low-k material by hydrogen and oxygen plasma treatments.

According to an embodiment of the present disclosure, a method for manufacturing an interconnecting metal layer is provided for a semiconductor device, and the semiconductor device includes a gate layer, a dielectric layer and an insulating layer. The dielectric layer is disposed on one side of the gate layer, the insulating layer is disposed on another side of the gate layer, and the method for manufacturing the interconnecting metal layer includes the following steps. A trench is formed, the trench passes through the dielectric layer and the gate layer, and an epitaxial layer is formed at the bottom of the trench. A sidewall liner is formed on the sidewall of the trench, and one end of the sidewall liner is connected to the epitaxial layer. Hydrogen and oxygen plasma treatments are performed on the sidewall liner to convert the sidewall liner from a high-k material to a low-k material.

According to an embodiment of the present disclosure, a method for manufacturing an interconnecting metal layer is provided for a semiconductor device, and the semiconductor device includes a gate layer, a dielectric layer and an insulating layer. The dielectric layer is disposed on one side of the gate layer, the insulating layer is disposed on another side of the gate layer, and the method for manufacturing the interconnecting metal layer includes the following steps. A first trench and a second trench are formed, the first trench and the second trench pass through the dielectric layer and the gate layer, a first epitaxial layer is formed at the bottom of the first trench, and a second epitaxial layer is formed at the bottom of the second trench. A first sidewall liner is formed on the sidewall of the first trench, and one end of the first sidewall liner is connected to the first epitaxial layer. A second sidewall liner is formed on the sidewall of the second trench, and one end of the second sidewall liner is connected to the second epitaxial layer. hydrogen and oxygen plasma treatments are performed on the first sidewall liner and the second sidewall liner, so that the first sidewall liner and the second sidewall liner are converted from a high-k material to a low-k material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising
a gate layer;
a dielectric layer disposed on a side of the gate layer;
an insulating layer disposed on another side of the gate layer;
an epitaxial layer disposed on the insulating layer; and
a sidewall liner passing through the dielectric layer and the gate layer, one end of the sidewall liner is connected to the epitaxial layer, wherein the sidewall liner is converted from a high dielectric constant material to a low dielectric constant material by hydrogen and oxygen plasma treatments.

2. The semiconductor device according to claim 1, further comprising a metal layer, the metal layer is connected to the epitaxial layer, and the sidewall liner is separated from the metal layer and the gate layer.

3. The semiconductor device according to claim 1, wherein the metal layer comprises tungsten, and the semiconductor device further comprises a seed layer and a metal silicide formed on a bottom of the metal layer.

4. The semiconductor device according to claim 1, wherein the high dielectric constant material comprises silicon nitride (SiNx), and the low dielectric constant material comprises silicon dioxide (SiO₂).

5. The semiconductor device according to claim 4, wherein the hydrogen and oxygen plasma treatments comprise an oxygen ion plasma is introduced to react with silicon nitride (SiNx) to generate silicon dioxide (SiO₂).

6. A method for manufacturing an interconnecting metal layer for a semiconductor device, the semiconductor device comprising a gate layer, a dielectric layer and an insulating layer, the dielectric layer being disposed on a side of the gate layer, the insulating layer being disposed on another side of the gate layer, and the method for manufacturing the interconnecting metal layer comprising:
forming a trench, the trench passing through the dielectric layer and the gate layer, and an epitaxial layer being formed at a bottom of the trench;
forming a sidewall liner on a sidewall of the trench, and one end of the sidewall liner being connected to the epitaxial layer; and
performing hydrogen and oxygen plasma treatments on the sidewall liner to convert the sidewall liner from a high dielectric constant material to a low dielectric constant material.

7. The method according to claim 6, further comprising forming a metal layer in the trench, the metal layer is connected to the epitaxial layer, and the sidewall liner is separated from the metal layer and the gate layer.

8. The method according to claim 7, wherein before forming the metal layer in the trench, the method further comprises forming a metal silicide and a seed layer at the bottom of the trench, the metal silicide is located between the seed layer and the epitaxial layer.

9. The method according to claim 6, wherein converting the sidewall liner from the high dielectric constant material to the low dielectric constant material comprises introducing an oxygen ion plasma to react with silicon nitride (SiNx) to generate silicon dioxide (SiO₂).

10. The method according to claim 9, wherein during the hydrogen and oxygen plasma treatments, the sidewall liner comprises a surface layer and a bottom layer, the bottom layer is silicon nitride (SiNx), and the surface layer is silicon dioxide (SiO₂) generated by the reaction of the silicon nitride (SiNx) with oxygen ions.

11. The method according to claim 10, further comprising reacting the silicon nitride of the bottom layer with oxygen ions to generate silicon dioxide (SiO₂).

12. A method for manufacturing an interconnecting metal layer for a semiconductor device, the semiconductor device comprising a gate layer, a dielectric layer and an insulating layer, the dielectric layer being disposed on a side of the gate layer, the insulating layer being disposed on another side of the gate layer, and the method for manufacturing the interconnecting metal layer comprising:
forming a first trench and a second trench, the first trench and the second trench pass through the dielectric layer and the gate layer, and a first epitaxial layer being formed on the first trench bottom, a second epitaxial layer being formed on the bottom of the second trench;
forming a first sidewall liner on a sidewall of the first trench, and one end of the first sidewall liner being connected to the first epitaxial layer;
forming a second sidewall liner on a sidewall of the second trench, and one end of the second sidewall liner being connected to the second epitaxial layer; and
performing hydrogen and oxygen plasma treatments on the first sidewall liner and the second sidewall liner to convert the first sidewall liner and the second sidewall liner from a high dielectric constant material to a low dielectric constant material material.

13. The method according to claim 12, further comprising:
forming a first metal layer in the first trench, the first metal layer being connected with the first epitaxial layer, and the first sidewall liner layer being separated from the first metal layer and the gate layer; and
forming a second metal layer in the second trench, the second metal layer being connected with the second epitaxial layer, and the second sidewall liner being separated from the second metal layer and the gate layer.

14. The method according to claim 13, wherein before forming the first metal layer in the first trench, the method further comprises forming a metal silicide and a seed layer at the bottom of the first trench, the metal silicide is located between the seed layer and the first epitaxial layer.

15. The method according to claim 13, wherein before forming the second metal layer in the second trench, the method further comprises forming a metal silicide and a sublayer at the bottom of the second trench, the metal silicide is located between the seed layer and the second epitaxial layer.

16. The method according to claim 12, wherein during the hydrogen and oxygen plasma treatments, converting the first and the second sidewall liner from the high dielectric constant material to the low dielectric constant material comprises introducing oxygen ion plasma to react with silicon nitride (SiNx) to generate silicon dioxide (SiO₂).

17. The method according to claim 16, wherein the first and the second sidewall liner respectively comprise a surface layer and a bottom layer, the bottom layer is silicon nitride (SiNx), and the surface layer is silicon dioxide (SiO₂) generated by the reaction of the silicon nitride (SiNx) with oxygen ions.

18. The method according to claim 17, further comprising reacting the silicon nitride of the bottom layer with oxygen ions to generate silicon dioxide (SiO₂).

19. The method according to claim 13, wherein the first epitaxial layer and the second epitaxial layer serve as a source and a drain of a transistor, and the gate layer includes a gate electrode located between the metal layer and the second metal layer.

20. The method according to claim 12, wherein the first and second epitaxial layers are silicon germanium compounds.
